(19) United States
(12) Patent Application Publication
(10) Pub. No.: US 2008/0100377 A1
(43) Pub. Date: May 1, 2008

(54) Methods and devices for providing an amplitude estimate of a time varying signal

(76) Inventor: Douglas Kerns, Sierra Madre, CA (US)

Correspondence Address: Darryl G. Walker, Suite 235, 300 South First Street, San Jose, CA, 95113, US

(21) Appl. No.: 11/903,358

(22) Filed: Sep. 21, 2007

Related U.S. Application Data
(60) Provisional application No. 60/855,385, filed on Oct. 31, 2006.

(51) Int. Cl. H01L 29/00

(52) U.S. Cl. 327/581

(57) ABSTRACT

A JFET transistor device configured to provide an amplitude estimate of a time varying input signal, and associated methods for using such a device, are disclosed. An exemplary JFET transistor device includes a gate region and a substrate (back gate, or the like), at least one of which is at a floating potential and the other of which is at a circuit common potential; and a channel region, connecting a source region and a drain region of the transistor device for receiving a time varying input signal at a first location and for producing an output signal related to amplitude of the time varying signal at a second location.

This application claims the benefit of U.S. Provisional Patent Application Ser. No. 60/855,385, filed Oct. 31, 2006, the contents of which are incorporated by reference herein.

### TECHNICAL FIELD

Methods and devices for providing an amplitude estimate of a time varying signal are disclosed, along with modular implementations of such devices.

### BACKGROUND OF THE INVENTION

Devices are known for estimating amplitude of time varying electrical signals in circuit devices used for a variety of applications. As referenced herein, an “estimate” of an amplitude can be a signal value derived from the time varying signal which corresponds to an actual value, an approximated value or any other value which is related to (e.g., proportional to) the actual amplitude of the time varying signal. The applications include, but are not limited to, radio signal detection, automatic gain control, sensor and transducer read-out electronics, activity monitors and so forth.

An amplitude estimation circuit produces an electrical signal output which varies in a predictable manner relative to the amplitude of an input electrical signal under examination. The input signal can be either a current or voltage. Similarly, the output signal can be a current or voltage, depending on the desired application.

### SUMMARY OF THE INVENTION

A junction field effect transistor (JFET) device configured to provide an amplitude estimate of a time varying input signal is disclosed which comprises: a gate region and a substrate, at least one of which is at a floating potential and the other of which is at a circuit common potential; and a channel region, connecting a source region and a drain region of the transistor device for receiving a time varying input signal at a first location and for producing an output signal related to amplitude of the time varying signal at a second location.

According to the embodiments, JFET device may be configured to provide an amplitude estimate of a time varying input signal and may include a gate region that is essentially floating. A channel region may be coupled between a source/drain region and a drain/source region. The source/drain region may receive the time varying input signal and the drain source may be coupled to provide an output signal related to an amplitude of the time varying input signal.

According to the embodiments, a circuit device may provide automatic gain control. The circuit device may include a JFET device having a gate region, a source/drain region, and a drain/source region. The gate region may be essentially floating. A signal input circuit may be coupled to the source/drain region and receives a time varying input signal. A signal output circuit may be coupled to the drain/source region to provide a controlled gain signal.

According to the embodiments, a method for providing an output signal related to an amplitude of a time varying input signal may include the steps of establishing a transistor device gate region at essentially a floating potential, supplying a time varying input signal to a channel region used to connect a source region and a drain region of the transistor device, and detecting an output signal of the channel region as an estimation of an amplitude of the time varying input signal.

A circuit device is disclosed for providing automatic gain control, comprising: a JFET transistor device having a gate region, a channel region, and a substrate, wherein at least one of the gate region and the substrate is placed at a floating potential. The circuit device includes a signal input circuit; and a signal output circuit.

A method is disclosed for providing an output signal is related to an amplitude of a time varying input signal. The method comprises: establishing at least one of a transistor device gate region and substrate at a floating potential; supplying a time varying input signal to a channel region used to connect a source region and a drain region of the transistor device; and detecting an output signal of the channel region as an estimation of an amplitude of the time varying input signal.

A method for establishing a circuit design is disclosed which comprises: creating a library of modular circuit components, wherein at least one circuit component is a JFET device having a gate region, a channel region and a substrate, wherein at least one of the gate region and the substrate is placed at a floating potential. The method includes selecting the circuit component for inclusion in an electrical circuit, such that a time varying input signal is applied to a first contact of the channel region; and a second contact of the channel region provides a signal output related to an estimate of an amplitude of the time varying input signal.

An apparatus is disclosed for providing an amplitude of time-varying signal. The apparatus comprises a first conductive path across a junction between a gate region of a first material having a first conductivity type, and a second material constituting a channel having a second conductivity type. A signal input is connected to a first portion of the channel for receiving charge of a time varying input signal; and a signal output is connected to a second portion of the channel for producing a charge having a value related to an amplitude of the time varying input signal.

### BRIEF DESCRIPTION OF THE DRAWINGS

FIG. 1A is a cross sectional diagram of an n-channel junction field effect transistor (JFET) device that may be used in a circuit providing an average amplitude signal output according to an embodiment.

FIG. 1B is a cross sectional diagram of a p-channel junction field effect transistor (JFET) device that may be used in a circuit providing an average amplitude signal output according to an embodiment.

FIG. 1C is a cross sectional diagram of an n-channel junction field effect transistor (JFET) device that may be used in a circuit providing an average amplitude signal output according to an embodiment.

FIG. 1D is a cross sectional diagram of a p-channel junction field effect transistor (JFET) device that may be used in a circuit providing an average amplitude signal output according to an embodiment.

FIGS. 2A-2D show exemplary embodiments of automatic gain control (AGC) devices which can be implemented using the n-channel transistors of FIGS. 1A and 1C.

FIGS. 3A-3D show exemplary embodiments of automatic gain control (AGC) devices which can be implemented using the p-channel transistors of FIGS. 1B and 1D.

### DETAILED DESCRIPTION OF THE EMBODIMENTS

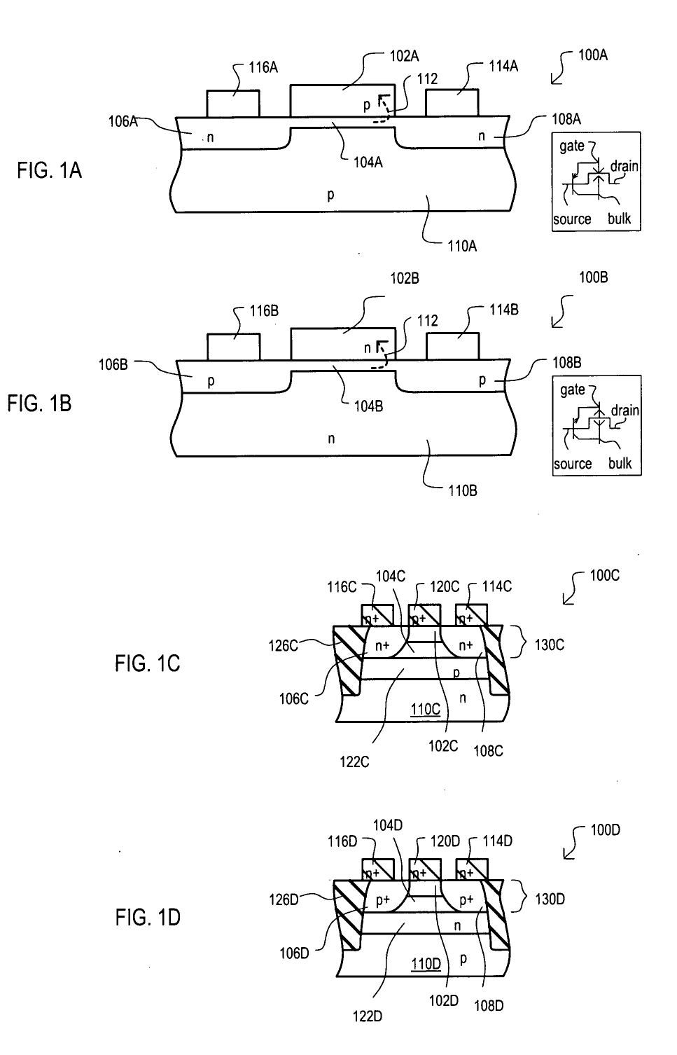

FIG. 1A illustrates a cross-sectional view of an exemplary junction field effect transistor (JFET) transistor device 100A configured to provide an amplitude of a time varying input signal. The JFET 100A includes a gate region 102A and a substrate 110A, at least one of which is at a floating potential. The gate region 102A can be configured, for example, of p-type conductivity material.

As referenced herein, a “floating” potential means that a contact connected to, for example, the gate region 102A, is either left unconnected (i.e., open) or connected to a circuit component that would reduce or prevent current flow to the gate. For example, a circuit component such as another JFET gate region, a MOSFET gate region, a capacitor, a reverse biased diode or other suitable device, can be connected to the gate region 102A (or to substrate 110A) such that the contact of the gate region is connected to a variable supply current which cannot sustain a continuous flow of current to the gate region. The JFET 100A includes a channel region 104A, connecting a source region 106A and a drain region 108A of the transistor device. The channel region can receive a time varying input signal at a first location, and can produce an output signal related to amplitude of the time varying signal at a second location. In the exemplary FIG. 1A embodiment, the channel region is formed as an n-type channel of n-type conductivity material.

The JFET 100A of FIG. 1A also includes the substrate 110A, which is represented as a bulk region of p-type conductivity material. With gate region 102A at a floating potential, the substrate 110A, in an exemplary embodiment, is connected to a circuit common potential (e.g., the common ground of a circuit within which the transistor is connected).

In the FIG. 1A exemplary embodiment, when a voltage is applied to a channel contact of the transistor device which exceeds a threshold voltage of a junction between the gate region 102A and the source region 106A (V_{GS}) a current is established in the gate region. This voltage is applied, for example, as the voltage of a time varying input signal to either the source or drain region. If, for example, the signal is applied to the drain region 108A, then an output signal produced at the source 106A will be a current that constitutes an estimated amplitude of either the voltage or current of the input signal applied to the drain region. Alternately, a gate-to-source voltage (V_{GS}) can be monitored as an output signal representative of the estimated amplitude.

The ability to provide an output current or voltage signal from the channel that is related to amplitude of an input signal applied to the channel results, at least in part, from the JFET 100A performing the functions of two separate devices. The JFET 100A functions across the source-to-drain channel as a JFET, but functions across the gate-to-source junction as a bipolar junction transistor (BJT). Current flow across the gate region 102A and bulk region 110A is controlled as a function of the voltage (or current) associated with the time varying input signal.

Because the gate region 102A joins the channel 104A through a p-n junction, minority charge carriers generated in the channel region can move into the gate region 102A. The dashed arrow 112 schematically illustrates a trajectory of a positive charge carrier from the channel 104A into the gate region 102A.

Similarly, negative charge carriers generated in the gate region 102A can cross into the channel region 104A. The movement of minority charge carriers from the gate region 102A into the channel 104A constitutes an electrical current, referred to herein as a junction leakage current. In the absence of other influences, the leakage current will transport charge between the channel 104A and the gate region 102A, thereby changing a voltage at the gate relative to the channel (e.g., a gate-to-source voltage V_{GS}) until the gate-to-channel voltage is sufficiently large to induce an opposing current flow equal in magnitude to the leakage current.

If the voltage between the p-type gate region 102A and the n-type channel 104A is sufficiently large, positive charge carriers from the gate region 102A can cross the p-n junction into the channel, constituting an electrical current. This current is referred to herein as a forward-biased gate current. This forward-biased gate current depends on the voltage between the gate region 102A and the channel 104A (e.g., the gate-to-source voltage V_{GS}). The dependency can be a strong non-linear function (e.g., almost exponential).

The inset of FIG. 1A illustrates an equivalent circuit for the transistor of FIG. 1A. The inset illustrates that gate current is dependent on the gate-channel voltage, especially the voltage across the gate-to-source junction. A junction leakage current will, in exemplary embodiments, be approximately constant, with some dependence on temperature and/or other environmental conditions.

In accordance with exemplary embodiments, the JFET 100A includes a first contact 114A connected to the channel region 102A by way of drain region 108A for receiving a time varying input signal. Although shown as being associated with the drain region 108A, the first contact can be associated with either the drain region 108A or the source region 106A, and serves as a signal input. The time varying input signal can be a digital signal, or it can be an analog signal.

A second contact 116A of the channel region provides for an output signal to be detected, the output signal being a signal representing an amplitude of the time varying input signal. In exemplary embodiments, this output signal is an estimate of an amplitude of the time varying input signal. A change in amplitude of the time varying input signal can produce a shift in an average voltage of the gate region, which in turn leads to a shift in the output signal detected on the contact 116A.

Given the floating nature of the gate region 102A, and the application of a time-varying input signal to the source region or the drain region, the channel region is configured to carry a charge which is substantially independent of charge conducted between the gate region and the channel region. This relationship results in an output signal from the JFET 100A being related to (e.g., an estimate of) an amplitude of time varying input signal.

Because the gate region 102A is uniformly capacitively coupled to the channel region, while the time varying input signal has stronger influence on the channel through the source region 106A, the time varying input signal will induce variations in the gate-to-channel voltage (e.g., the V_{GS} voltage) in proportion to the amplitude of the input signal. Given the strong non-linearity of the forward-biased gate current, the time-varying input signal will induce a shift in the average value of the gate voltage so that an aggregate total forward-biased gate current remains balanced with the junction leakage current. This shift in average gate voltage provides for output of an estimated amplitude of the time the varying input signal.

FIG. 1B shows a device similar to FIG. 1A. However, in the FIG. 1B embodiment, the transistor device 100B is a p-channel structure. Transistor device 100B comprising a JFET device that may be used in a circuit providing an average amplitude signal output may include similar constituents as transistor device 100A. Such constituents may have the same first 3 digits, but end in a “B” instead of an “A” and may have an opposite conductivity type. P-type becomes n-type and n-type becomes p-type.

Transistor device 100B includes a gate region 102B, a drain region 108B, a source region 106B, and a channel region 104B formed on a substrate 110B. Substrate 110B and gate region 102B may be doped n-type. Drain region 108B, source region 106B, and channel region 104B may be doped p-type. In this way, transistor device 100B may be a p-channel JFET.

Referring now to FIG. 1C, yet another embodiment of a JFET device that may be used in a circuit providing an average amplitude signal output is set forth in a cross-sectional schematic diagram and given the general reference character 100C.

The transistor device 100C comprising an amplitude estimation device may include similar constituents as transistor device 100A. Such constituents may have the same first 3 digits, but end in a “C” instead of an “A”.

Transistor device 100C may differ from transistor device 100A in that a second gate region 122C may be formed under the channel region 104C and on the substrate 110C. Transistor device 100C may also include isolation regions 126C formed by a shallow trench isolation (STI) method or the like.

Transistor device 100C may include a source terminal 116C, a drain terminal 118C, and a gate terminal 120C. The source terminal 116C and drain terminal 114C may be formed from n-type polysilicon, as just one example. The gate terminal 120C may be formed from p-type polysilicon. A diffusion step or the like may be used to form n-type source region 106C, n-type drain region 106C, and p-type gate region 102C by way of out diffusion from source terminal 114C, a drain terminal 116C, and a gate terminal 120C, respectively. The channel region 104C and substrate may be n-type and the gate region 122C may be p-type.

Referring now to FIG. 1 D, yet another embodiment of a JFET device that may be used in a circuit providing an average amplitude signal output is set forth in a cross-sectional schematic diagram and given the general reference character 100D.

The transistor device 100D comprising an amplitude estimation device may include similar constituents as transistor device 100B. Such constituents may have the same first 3 digits, but end in a “D” instead of an “B”.

Transistor device 100D may differ from transistor device 100B in that a second gate region 122D may be formed under the channel region 104C and on the substrate 110D. Transistor device 100D may also include isolation regions 126D formed by a shallow trench isolation (STI) method or the like.

Transistor device 100D may include a source terminal 116D, a drain terminal 118D, and a gate terminal 120D. The source terminal 116D and drain terminal 114D may be formed from p-type polysilicon, as just one example. The gate terminal 120D may be formed from n-type polysilicon. A diffusion step or the like may be used to form p-type source region 106D, p-type drain region 108D, and n-type gate region 102D by way of out diffusion from source terminal 114D, a drain terminal 116D, and a gate terminal 120D, respectively. The channel region 104D and substrate may be p-type and the gate region 122D may be n-type.

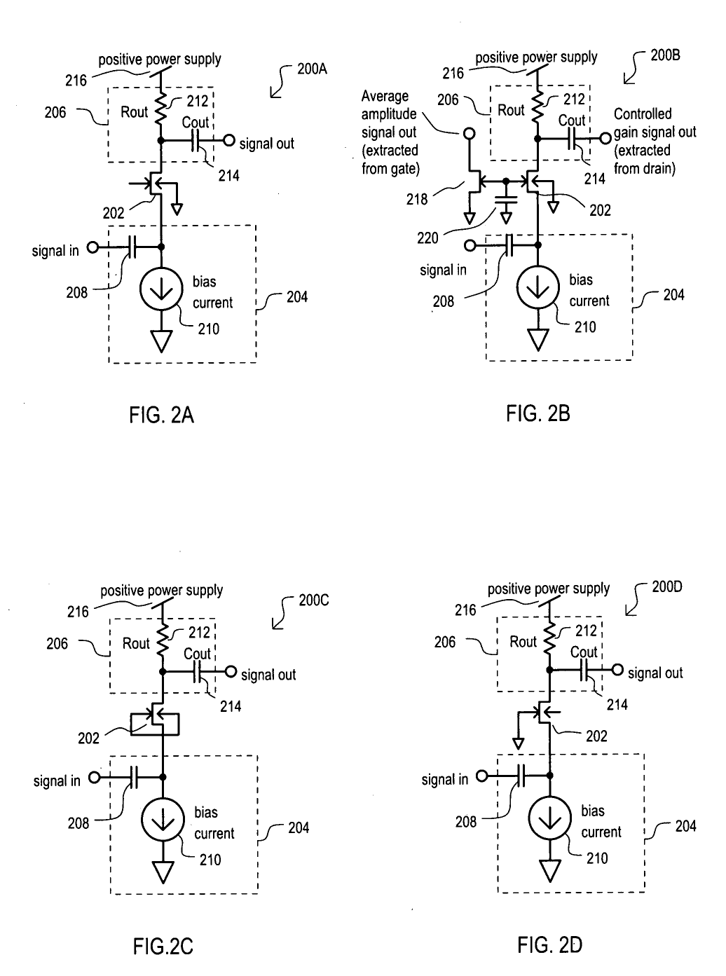

The exemplary transistor device as configured in FIGS. 1A and 1B can be used in a variety of circuits to exploit the amplitude estimation operation. One such example is an automatic gain control circuit as illustrated in FIG. 2A.

The FIG. 2A circuit device 200A includes a JFET transistor device 202 which can be configured as the JFET 100A of FIG. 1A or JFET 100C of FIG. 1C. The JFET 202 includes a gate region, a channel region, and a substrate (back gate) as previously described, wherein the gate region is placed at a floating potential. The circuit device also includes a signal input circuit 204 and a signal output circuit 206. A body/substrate or a back gate of JFET 202 may be connected to a reference potential, in this case a ground potential.

In an exemplary embodiment, the signal input circuit 204 can include a first contact connected to the channel region to supply a time varying input signal to the channel region. In an exemplary embodiment, the time varying input signal can be supplied to a source/drain of the JFET 202. The input circuit 204 can include optional circuit components including, but not limited to an input capacitor 208 and/or a bias current 210. Signal input circuit 204 may include a capacitor 208 having a first terminal connected to receive the input signal signal in and a second terminal connected to a first terminal of bias current 210 and a source of JFET 202. Bias current 210 may have a second terminal connected to a reference potential (ground). JFET 202 may have a backgate, substrate, or the like connected to the reference potential (ground).

The signal output circuit 206 can similarly include an output contact for sensing current or gate-to-source voltage. In addition, the signal output circuit 206 can include circuit components including, but not limited to, an RC circuit configured of a resistor 212, capacitor 214 and a positive power supply 216. The circuit output 206 may include a capacitor 214 having a first terminal connected to a drain/source of JFET 202 and a second terminal connected to provide the output signal signal out. Resistor 212 may have a first terminal connected to a positive power supply 216 and a second terminal connected to the drain/source of JFET 202.

In the FIG. 2A embodiment, changes in an average gate voltage of the JFET 202 can influence channel conductance of the transistor and thereby modulate an amplitude of an output signal. The performance of the FIG. 2A circuit device can be modified in any of numerous ways readily apparent to those skilled in the art including, but not limited to, the modifications illustrated in FIG. 2B.

In FIG. 2B, the gate region of a transistor 202 remains floating, as with the FIG. 2A circuit. However, in the FIG. 2B embodiment, the gate is connected via another JFET 218 of similar configuration as JFET 202, and/or a capacitor 220. In particular, JFET 218 may include a source/drain terminal connected to a reference potential (ground), a drain/source terminal connected to provide an average amplitude signal output, and a gate terminal commonly connected to the gate terminal of JFET 202. Capacitor 220 may have a first terminal commonly connected to the gate terminals of JFETs (202 and 218) and a second terminal connected to a reference potential (ground). In this way, gate terminals of JFETs (202 and 218) may be essentially floating and a potential may develop on the gate terminals of JFETs (202 and 218) that is proportional to an amplitude of the input signal signal in. As the potential on the common gate terminal of JFETs (202 and 218) changes, the impedance of JFET 218 changes. In this way, an average amplitude of input signal signal in may be determined by detecting, for example, a current magnitude flowing through JFET 218 at a drain terminal. JFET 218 may operate as a variable current supply. The variable current supply may provide a current proportional to an amplitude of the input signal signal in.

JFET 218 and capacitor 220 may be conceptualized as a gate circuit, that provides a variable current supply in accordance with a potential provided on the essentially floating gate of JFET 202. The potential on the essentially floating gate of JFET 202 may be an average amplitude signal based on input signal signal in.

In the embodiments of FIGS. 2A and 2B, the body/substrate or back gate region of the JFET 202 is shown as being connected to a reference potential, in this case a ground potential. However, the bulk region can alternately be tied to a bias voltage or can be left open.

Those skilled in the art will appreciate that the materials selected for configuration of the transistor can be of any known type. In alternate embodiments, strained silicon can optionally be used to form a layer on the substrate beneath the gate region in an effort to improve conductivity of the channel region. Although use of strained silicon can change device characteristics and impact device size, functional and basic structural features can remain unaffected. Referring to FIG. 1A, an optional strained silicon layer can be deposited on the substrate bulk regions 110A and 110B to form the channels 104A and 104B. Such an option can enhance transistor switching speed in a reduced size transistor device.

FIGS. 2C and 2D illustrate the circuit devices of FIGS. 2A and 2B, respectively, but with modifications to the gate region and substrate region. More particularly, in FIG. 2C, the transistor 202 includes a gate region tied to the bulk region (or back gate region). In FIG. 2D, the gate region is grounded and the bulk region (or back gate region) is left at a floating potential.

Those skilled in the art will appreciate that the components shown (e.g., RC values) can be selected as a function of the desired frequency range of operation of the time varying input signal. The time varying input signal can for example, range from the low audible range (e.g., <1 Hz) to microwave frequencies, or higher. In selecting a low end of operating frequency, factors such as leakage rate on the gate can be taken into consideration. At the upper end of the frequency range, parasitic capacitance at the source and drain can be taken into consideration. The bias voltage can similarly be selected as a function of the desired operation and input signal frequency (e.g., the bias voltage can be within the range of 50 mV to 500 mV, or lesser or greater). For a lower frequency input audio signal, a bias voltage of, for example, 20-50 mV can be used, while a higher bias voltage of, for example, 500-600 mV can be used for a microwave input signal.

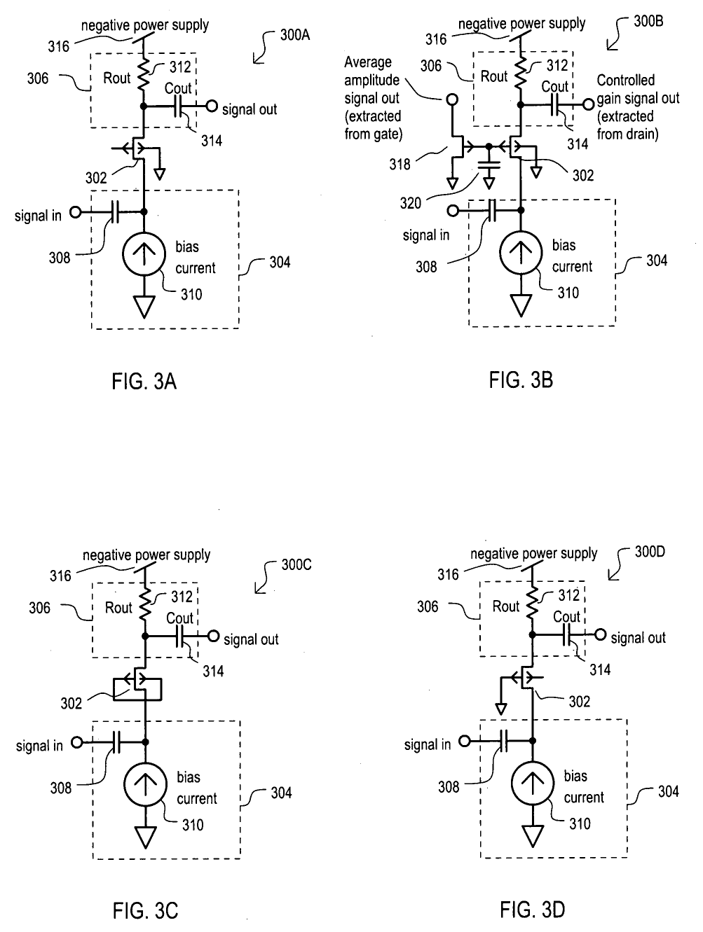

FIGS. 3A-3D illustrate circuit devices 300 similar to those described with respect to FIG. 2. In the FIG. 3A-D embodiments, each of the circuit devices of FIGS. 2A-2D has been reconfigured using p-channel devices, wherein elements of FIGS. 3A-3D are labeled using “300” designations to replace their counterpart “200” designation in FIGS. 2A-2D, respectively. In particular, the circuit devices (300A to 300D) in FIGS. 3A to 3D use the p-channel JFETs (100B and 100D) as JFET 302. A negative power supply potential may be used instead of positive power supply. Although, a negative power supply is illustrated, a ground potential may be provided instead and the second terminal of bias current 310 may have a positive power supply. In other words, the second terminal of resistor 312 may only necessarily be connected to a supply potential that is at a lower potential than the potential of the second terminal of bias current 310.

Those skilled in the art will appreciate that the automatic gain control circuits described in FIGS. 2 and 3 are way by example only, and that numerous other circuit devices can be configured. For example, the amplitude estimator of FIGS. 1A and 1B can be used in wireless receivers for radio and optical signals, for mass storage read channel circuitry, and sensor and transducer interface circuits, and/or in any other circuit which requires or involves the use of amplitude estimation.

An exemplary method for providing an output signal proportional to the amplitude of the time varying input signal is also disclosed herein. In accordance with exemplary embodiments, the method can include establishing at least one of a transistor device gate region and a substrate at a floating potential, as described with respect to FIG. 1A. A time varying input signal can be supplied to a channel region of the transistor device to connect a source region and drain region of the transistor device. An output signal of the channel region can be detected as an estimation of an amplitude of the time varying input signal.

In alternate embodiments, a circuit design can be established using a method which involves the transistor device as described herein. In such a method, a library of modular circuit components can be created, wherein at least one of the circuit components is a JFET device having a gate region, a channel region and a substrate, wherein at least one of the gate region and the substrate is placed at a floating potential. In accordance with an exemplary embodiment, the circuit component can be selected for inclusion in an electrical circuit, such that a time varying input signal is applied to a first contact of the channel region. A second contact of the channel region supplies a signal output proportional to an estimate of an amplitude of the time varying signal.

It will be appreciated by those skilled in the art that the present invention can be embodied in other specific forms without departing from the spirit or essential characteristics thereof. The presently disclosed embodiments are therefore considered in all respects to be illustrative and not restricted. The scope of the invention is indicated by the appended claims rather than the foregoing description and all changes that come within the meaning and range and equivalence thereof are intended to be embraced therein.

Reference in the description to “one embodiment” or “an embodiment” means that a particular feature, structure, or characteristic described in connection with the embodiment is included in at least one embodiment of the invention. The appearance of the phrase “in one embodiment” in various places in the specification do not necessarily all refer to the same embodiment. The term “to couple” or “electrically connect” as used herein may include both to directly and to indirectly connect through one or more intervening components.

Further it is understood that the embodiments of the invention may be practiced in the absence of an element or step not specifically disclosed. That is an inventive feature of the invention may include an elimination of an element.

While various particular embodiments set forth herein have been described in detail, the present invention could be subject to various changes, substitutions, and alterations without departing from the spirit and scope of the invention. Accordingly, the present invention is intended to be limited only as defined by the appended claims.

What is claimed is:

1. A junction field effect transistor (JFET) device configured to provide an amplitude estimate of a time varying input signal, comprising:
a gate region which is essentially floating; and
a channel region coupling a source/drain region to a drain/source region, the source/drain region coupled to receive the time varying input signal and the drain/source region coupled to provide an output signal related to an amplitude of the time varying input signal.

2. The JFET device of claim 1, wherein the voltage amplitude of the time varying input signal exceeds a threshold voltage of a junction between the gate region and the source/drain region of the JFET device to establish a current in the gate region.

3. The JFET device of claim 1, wherein a change in amplitude of the time varying input signal produces a shift in an average voltage of the gate region.

4. The JFET device of claim 1, wherein the output signal represents an estimated amplitude of the time varying input signal.

5. A circuit device for providing automatic gain control, comprising
a junction field effect transistor (JFET) device having a gate region, a source/drain region and, a drain/source region, the source/drain region and the drain/source region coupled together by a channel region, wherein the gate region is essentially floating;
a signal input circuit coupled to the source/drain region and is coupled to receive a time varying input signal; and
a signal output circuit coupled to the drain/source region to provide a controlled gain signal.

6. The circuit device of claim 5, wherein the signal input circuit is electrically connected to the source/drain region, and the signal output circuit is electrically connected to the drain/source region.

7. The circuit device of claim 5, wherein the signal input circuit includes:
a capacitor having a first capacitor terminal for receiving the time varying input signal, the capacitor having a second capacitor terminal; and
a bias current generator having a first bias generator terminal coupled to the the second capacitor terminal and the source/drain region of the JFET device.

8. The circuit device of claim 5, wherein the output circuit includes:
a resistor having a first resistor terminal coupled to a power supply and a second resistor terminal coupled to the drain/source region; and
a capacitor having a first capacitor terminal coupled to the drain/source region of the JFET device and a second capacitor terminal coupled to provide the controlled gain signal.

9. The circuit device of claim 5, wherein the gate region is coupled with a gate circuit to produce a variable current supply and the gate circuit includes at least one of a transistor and a capacitor, the transistor includes a gate terminal commonly coupled with a first capacitor terminal of the capacitor to the gate region of the JFET device.

10. The circuit device of claim 5, wherein JFET device includes a back gate region.

11. The circuit device of claim 10, wherein the back gate region is connected to a reference potential.

12. The circuit device of claim 10, wherein the gate region and back gate region are connected.

13. The circuit device of claim 10, wherein the gate region is connected to a reference potential and the back gate region is essentially floating.

14. A method for providing an output signal related to an amplitude of a time varying input signal, the method comprising the steps of:
establishing a transistor device gate region at essentially a floating potential;
supplying a time varying input signal to a channel region used to connect a source region and the drain region of the transistor device; and
detecting an output signal of the channel region as an estimation of an amplitude of the time varying input signal.

15. The method according to claim 14, wherein a change in amplitude of the time varying input signal produces a shift in an average voltage of the gate region.

16. A method of converting changes in an average gate voltage of a junction field effect transistor (JFET) to changes in a channel conductance of the JFET to provide an output signal representing an amplitude of a time varying input signal.

17. The method of claim 16, wherein the output signal is an estimate of the amplitude of the time varying input signal.

18. The method of claim 16, wherein the JFET is coupled to receive the time varying input signal at a source/drain region and coupled to provide the output signal at a drain/source region.

19. The method of claim 18, wherein the JFET includes a back gate formed in a substrate and a front gate formed above the substrate and the average gate voltage is generated at the front gate.

20. The method of claim 18, wherein the front gate and the back gate are connected.

21. The method of claim 19, wherein the back gate is connected to a reference potential.

22. The method of claim 18, wherein the JFET includes a back gate formed in a substrate and a front gate formed above the substrate and the average gate voltage is generated at the back gate.

23. The method of claim 22, wherein the front gate is connected to a reference potential.
